(19) United States
(12) Patent Application Publication
(10) Pub. No.: US 2015/0243872 A1
(43) Pub. Date: Aug. 27, 2015

(54) APPARATUS AND METHODS FOR HEAT-TO-ELECTRICAL ENERGY CONVERSION FROM A MOLDING PROCESS

(71) Applicant: George E. Danis, Hudson, MA (US)

(72) Inventor: George E. Danis, Hudson, MA (US)

(21) Appl. No.: 14/629,366

(22) Filed: Feb. 23, 2015

Related U.S. Application Data
(60) Provisional application No. 61/944,712, filed on Feb. 26, 2014.

(51) Int. Cl. H01L 35/32; B29B 13/04; B29B 13/02

(52) U.S. Cl. CPC H01L 35/32; B29B 13/02; B29B 13/04

(57) ABSTRACT

The disclosed technology may include a waste energy harvesting system for recapturing and converting excess heat from the manufacturing process, such as a molding process, to electricity. The recaptured energy may replace or supplement existing cooling equipment and reduce overall energy consumption for the molding process. The disclosed technology may include an augmentation device for heating a portion of a manufacturing machine, such as a barrel of an injection molding machine, while also generating a cold exterior surface temperature used to cool a portion of the machine. This may reduce the amount of time required to warm the material inside the barrel of the molding machine and/or cool the mold after it is injected with hot material from the barrel.

### RELATED APPLICATIONS

The present application claims priority to U.S. Provisional Application No. 61/944,712, filed Feb. 26, 2014, the contents of which is hereby incorporated by reference in its entirety.

### FIELD OF INVENTION

This invention relates generally to energy conversion. More particularly, in certain embodiments, the disclosed technology relates to apparatus and methods for capturing waste heat from manufacturing equipment and converting the heat to electricity. In certain embodiments, the disclosed technology relates to apparatus and methods for providing heating and cooling to manufacturing equipment.

### BACKGROUND

Energy used by manufacturing constitutes a significant portion of all energy use in the United States. Both heating and cooling may be required for unit operations in a manufacturing process in which temperature must be raised and then lowered (or vice versa). Thermal cycling of such unit operations is energy intensive and costly.

For example, injection molding requires thermal cycling. Material is initially fed into a barrel where it is heated above its glass transition temperature by application of heat to the barrel so that it can flow into the mold. The barrel may be pressurized after the material is heated above glass transition. The material is then injected into a mold via a nozzle. The mold contains a cavity which receives the material from the nozzle through a small opening in the mold. A sufficient amount of material is supplied to the mold to fill the cavity. Once the material is in the mold, it must solidify before the mold can be opened to remove the formed part.

In some cases, the material must cool for a significant amount of time in order to solidify. A cooling system may be used to cool the mold and reduce the amount of time it takes to solidify the material. A cooling system may, for example, pass coolant through a series of holes in the mold that are connected to each other to form a continuous pathway. After the mold has been cooled for a sufficient amount of time, the mold may be opened to remove the injection molded piece.

Both the heating and cooling systems used, for example, in the injection molding process require a significant amount of energy. There is a continuing need for systems that improve the efficiency of manufacturing processes.

### SUMMARY

The disclosed technology relates generally to an apparatus and method for conversion of waste heat to electricity in a manufacturing process. The disclosed technology, in some implementations, relates to an apparatus and method for converting electricity to a hot and cold source that may be used, among other things, to reduce the warm-up time of an injection molding machine and/or to reduce the cool-down time of a mold used in an injection molding process.

In some implementations, the disclosed technology includes a waste energy harvesting system for recapturing and converting excess heat from a manufacturing process, such as a molding process, to electricity. In some implementations, the recaptured energy can replace or augment existing cooling equipment and reduce overall energy consumption for the molding process. In some implementations, the disclosed technology captures heat dissipated by the barrel and converts it into electricity using thermal electric converters (TECs). The electricity may be used to drive other equipment used in a manufacturing process. For example, the electricity may be used to reduce the overall energy used to mold plastic. The electrical energy may be used to operate or supplement the cooling system. The cooling system is a critical component because it ensures the plastic has solidified sufficiently before ejection from the tool.

The disclosed technology, in some implementations, includes an augmentation device used to heat a component of a manufacturing machine, such as a barrel of an injection molding machine, while also generating a cold exterior surface temperature used to cool the machine. The augmentation device may reduce the amount of time required, for example, to warm the material inside the barrel of the molding machine. Additionally, the augmentation device may reduce the amount of time and/or energy required to cool the mold after it is injected with hot material from the barrel.

The disclosed technology, in certain embodiments, includes a harvesting apparatus for converting waste energy from a barrel of a molding machine from heat to electricity. The harvesting apparatus may include an inner component core for capturing heat from a barrel of a molding machine; one or more thermal-to-electric converters coupled to the inner component core for converting heat to electrical energy; and an outer component surrounding at least a portion of the inner component core and the one or more thermal-to-electric converters, wherein the outer component is an insulator and assists in heat conduction from the barrel of the molding machine to the one or more thermal-to-electric converters and in containing thermal waste energy.

The disclosed technology, in certain embodiments, includes an augmentation apparatus for use with a molding machine. The augmentation apparatus may include one or more thermal-to-electric converters for converting electrical energy to a heat source and a cold source; an inner component core, coupled to the one or more thermal-to-electric converters, for applying heat to a barrel of a molding machine; an outer component surrounding at least a portion of the inner component core and the one or more thermal-to-electric converters, wherein the outer component is an insulator and assists in heat conduction from the one or more thermal-to-electric converters to the barrel of the molding machine and in containing thermal waste energy; and a heat exchanger located between the inner component core and the outer component, wherein the heat exchanger is coupled to the cold source and used to cool a heat transfer fluid.

In certain embodiments, the harvesting device includes two or more thermal-to-electric converters positioned along the barrel according to a desired temperature distribution along the length of the barrel. The inner component core may be in physical contact with the barrel of the molding machine. The one or more thermal-to-electric converters may be mounted on the inner component core. The one or more thermal-to-electric converters may be removable. The plurality of thermal-to-electric converters may be arranged in a grid. In certain embodiments, the inner component is made from copper, aluminum, and/or iron. In certain embodiments, the one or more thermal-to-electric are coupled to an energy management system and the energy management system is programmable to accommodate the material in a molding process. In certain embodiments, the one or more thermal-to-electric converters may be a single thermal-to-electric converter with a curved shape configured to wrap around the inner component core. In certain embodiments, each of the inner component core and the outer component has a two-piece design such that the harvesting apparatus is removable. In certain embodiments, the heat exchange fluid is a refrigerant.

The disclosed technology, in certain embodiments, includes a method of using a harvesting system for converting waste heat from a barrel of a molding machine to electricity. The method may include capturing, via an inner component core of a harvesting system, heat from a barrel of a molding machine, wherein the inner component is made from at least one material selected from the group consisting of copper, aluminum, and iron; and converting, via one or more thermal-to-electric converters coupled to the inner component core, the captured heat to electrical energy. The harvesting system may include an outer component surrounding at least a portion of the inner component core and the one or more thermal-to-electric converters, wherein the outer component is an insulator and assists in heat conduction from the barrel of the molding machine to the one or more thermal-to-electric converters. The harvesting system may be used to harvest waste heat from a molding machine and the electricity produced by the harvesting system may be used to augment a cooling system used to cool the mold of the molding machine.

The disclosed technology, in certain embodiments, includes a method of using an augmentation system with a molding machine. The method may include converting, via one or more thermal-to-electric converters, electrical energy to a heat source and a cold source; applying, via an inner component core coupled to the one or more thermal-to-electric converters, heat from the heat source to a barrel of a molding machine, wherein the inner component is made from at least one material selected from the group consisting of copper, aluminum, and iron; and cooling, via a heat exchanger coupled to the cold source, a heat transfer fluid, wherein the heat exchanger is located between the inner component core and an outer component. The outer component may surround at least a portion of the inner component core and the one or more thermal-to-electric converters. The outer component may be an insulator and assists in heat conduction from the one or more thermal-to-electric converters to the barrel of the molding machine.

### BRIEF DESCRIPTION OF THE FIGURES

The foregoing and other objects, aspects, features, and advantages of the present disclosure will become more apparent and better understood by referring to the following description taken in conjunction with the accompanying drawings, in which:

FIG. 1 is an illustration of an example energy harvesting system;

FIG. 2 is an illustration of an example energy harvesting device;

FIG. 3 is an illustration of an example construction of the inner component of an energy harvesting device;

FIG. 4 is an illustration of an example inner component conductive core;

FIG. 5 is a flowchart of an example method of using a harvesting device to converting waste heat from the barrel of a molding machine to electricity;

FIG. 6 is an illustration of an example augmentation device;

FIG. 7 is a cross sectional view of an example augmentation device;

FIG. 8 is a cross sectional view of an example thermal-to-electric converted mounted between a hot plate and a heat sink;

FIG. 9 is a flowchart of an example method of converting electrical energy to a heat source that is applied to a barrel of a molding machine to melt material inside the barrel and a cold source that is used to cool a portion of the molding machine;

FIG. 10 shows a block diagram of an exemplary cloud computing environment; and

FIG. 11 is a block diagram of a computing device and a mobile computing device.

The features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

In some implementations, the disclosed technology includes a waste energy harvesting system for recapturing and converting excess heat from the manufacturing process, such as a molding process, to electricity. In some implementations, the recaptured energy can replace or augment existing cooling equipment and reduce overall energy consumption for the molding process. The disclosed technology, in some implementations, includes an augmentation device for heating and/or cooling the manufacturing machine.

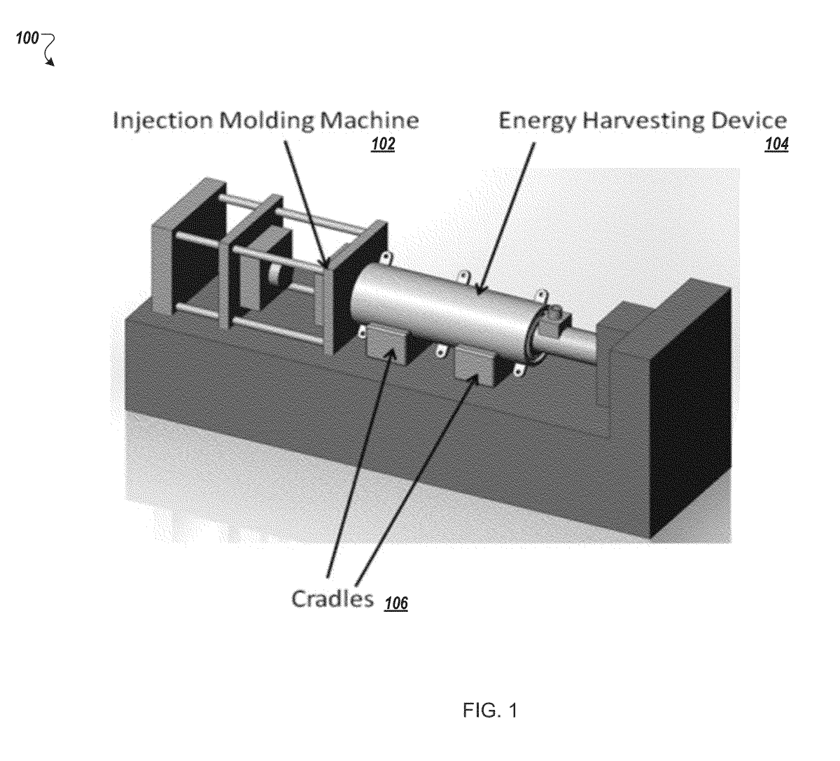

FIG. 1 is an illustration of an example energy harvesting system 100. In some implementations, the disclosed technology is used on a manufacturing machine 102. The manufacturing machine 102 may be an injection molding machine as shown in FIG. 1. The manufacturing machine 102 may also be an extrusion machine, liquid molding machine, reaction molding machine, blow mold machine, or other types of manufacturing machines,

In some implementations, the disclosed technology includes a harvesting device 104 as shown in FIG. 1. A harvesting device 104 may be used to capture waste heat from a manufacturing system 102, such as a molding system, and convert the waste heat to electricity. The harvesting device 104 may be installed around the barrel of the injection molding machine. In some implementations, cradles 106 are used to provide support for the harvesting device 104 and/or augmentation device. In some implementations, the device 104 is coupled to the machine 102, such as the barrel of the injection molding machine, without using the cradles 106.

In some implementations, the disclosed technology captures heat dissipated by the barrel and converts it into electricity using thermal-to-electric converters (TECs). The TECs may be a TEG High Temperature Module or Custom Thermoelectric TEC. The TECs may also be any thermoelectric, thermionic (e.g., ballistic thermionic or quasi diffusive thermionic), or thermo-photovoltaic energy converter. The electricity may be used to drive other equipment used in a manufacturing process. For example, the electricity may be used to reduce the overall energy used to mold plastic. The electrical energy may be used to operate or supplement the cooling system. The cooling system is a critical component because it ensures the plastic has solidified sufficiently before ejection from the tool.

In some implementations, the disclosed technology is used to heat a tool during startup. For example, the startup time for a molding tool can range from ten minutes to as long as a few hours. During this time, heat is applied to the tool to warm the tool to the required operating temperature. In some implementations, the harvesting device 104 transfers excess heat from one portion of the machine or another machine to heat the tool. In some implementations, the harvesting device 104 converts electrical energy to heat in order to warm a tool during startup.

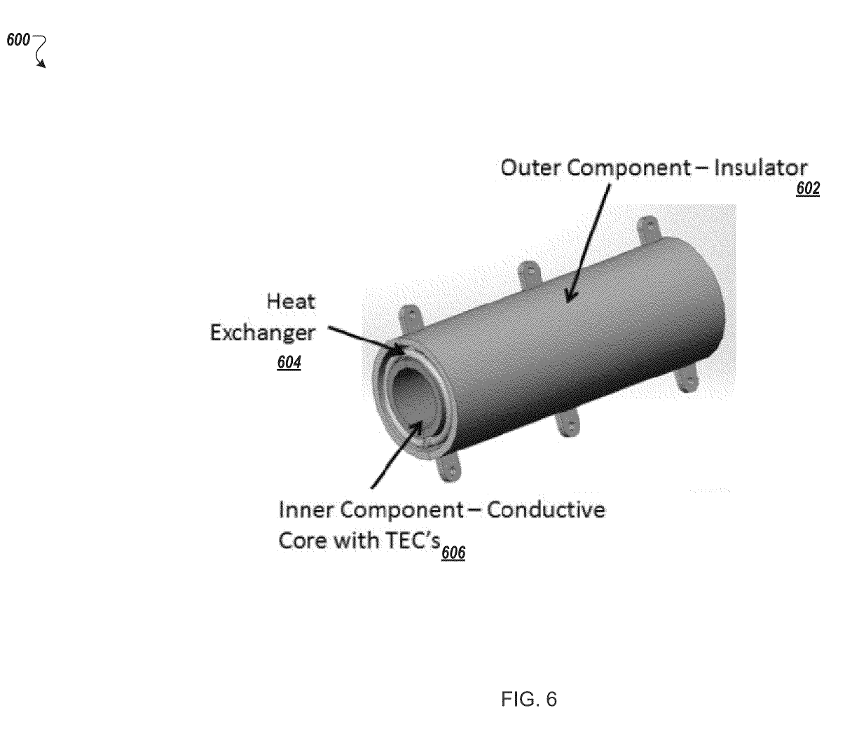

In some implementations, the disclosed technology includes an augmentation device for heating and/or cooling the manufacturing machine. An example augmentation device is shown in FIG. 6. In some implementations, the disclosed technology includes a combination harvesting and augmentation device.

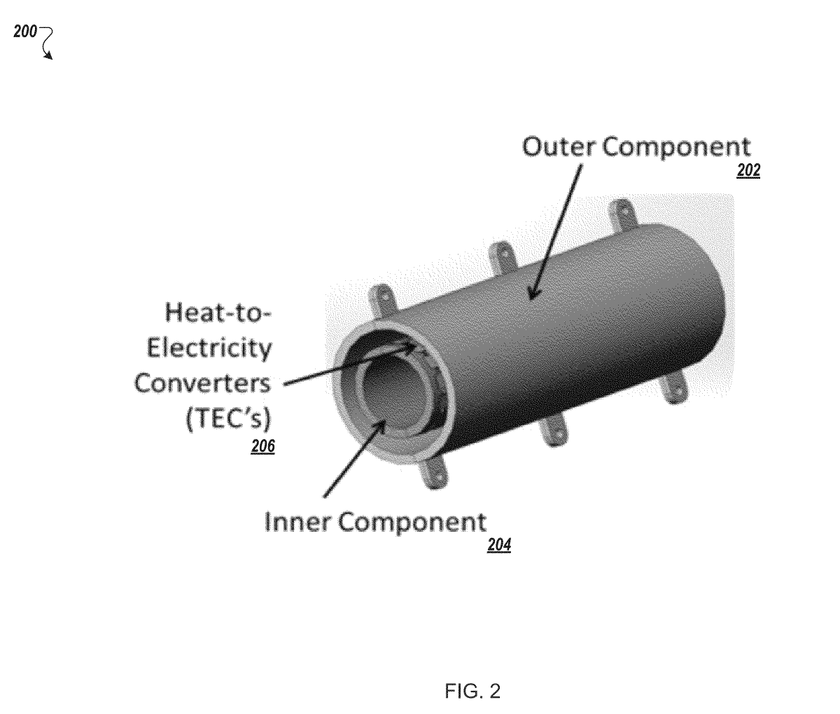

FIG. 2 is an illustration of an example energy harvesting device 200. In some implementations, the harvesting device 200 includes two half parts which can easily be assembled, for example, around the barrel of a molding machine. In some implementations, the harvesting device 200 is a one piece unit. The harvesting device 200 may be held using straps, bands, the cradles as shown in FIG. 1, other similar devices, or using a combination of devices. The harvesting device 200 may include an inner component 204. The inner component 204 may be made of a thermally conducive material such as aluminum, copper, or iron. The inner component 204 may be used to transfer heat form the barrel to the TECs 206. The inner component 204 may be in contact with a hot surface of the machine. For example, the inner component 204 may be in contact with the barrel of an injection molding machine. The TECs 206 may be mounted on the inner component 204 to maximize heat transfer. The outer component 202, in some implementations, is a protective sleeve. The outer component 202 may protect the TECs 206 and inner component 204 from excessive wear and damage that may, for example, be caused by operation of a machine in a manufacturing facility. The outer component 202 may act as an insulator to assist in heat conduction.

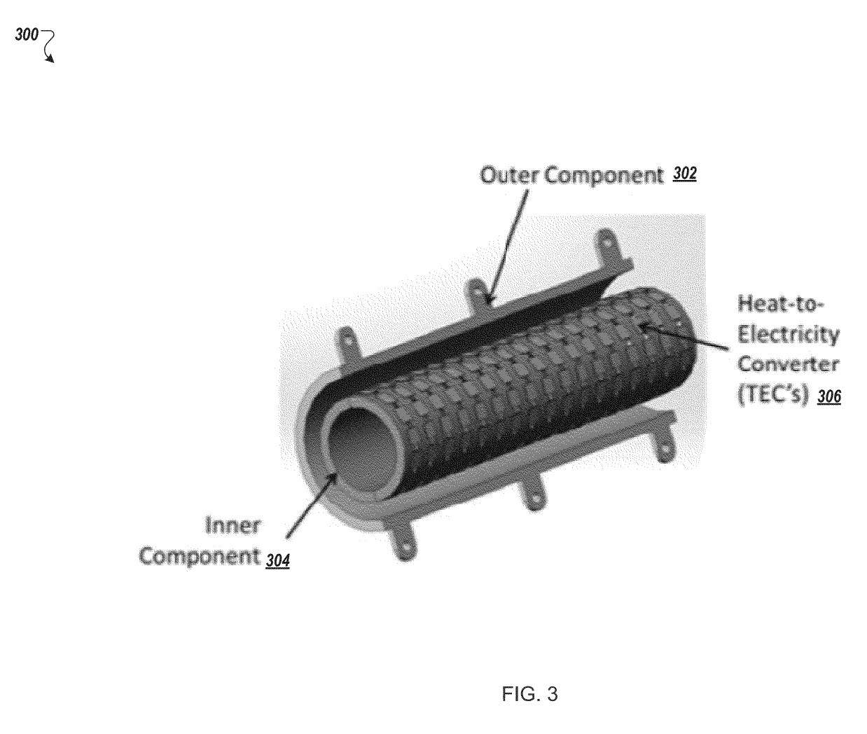

FIG. 3 is a cross sectional view of an example energy harvesting device 300. In some implementations, the TECs 306 are arranged in a grid pattern on the inner component 304 for high density packing. The electrical energy of each TEC 306 may be grouped to achieve a desired output. The TECs 306 may connected in series or in parallel. The device may include a switch that allows a user to switch between one or more configurations depending on the desired output from the harvesting device 300.

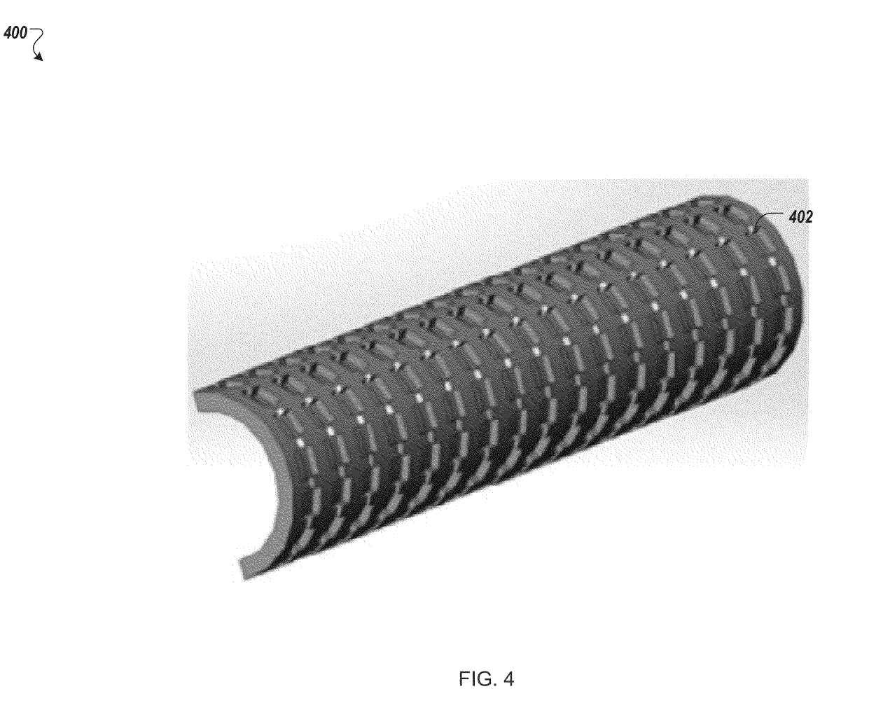

FIG. 4 is an illustration of an example inner component conductive core 400 and illustrates an example construction of the inner component of the harvesting device. In some implementations, the inner component 400 is a two-piece design. The inner component 400 may be made of a highly conductive material such as copper, aluminum, or iron. The inner component 400 may be primarily used for transferring energy from, for example, a barrel of an injection molding machine to TECs. In some implementations, the inner component 400 includes evenly spaced holes 402 which are used to place the TECs on the inner component 400.

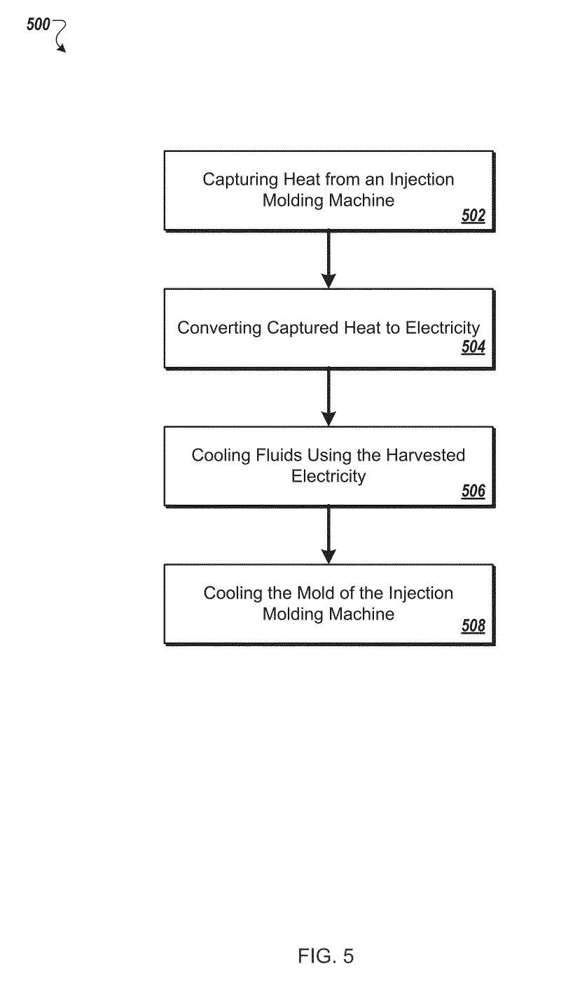

FIG. 5 is an example method 500 of using a harvesting device. The harvesting device may be used to convert waste heat from the barrel of a molding machine to electricity. The method 500 may include capturing (502) heat from an injection molding machine. An inner component core may be used for capturing heat from a barrel of a molding machine. The inner component is made from a conductive material such as copper, aluminum, or iron. The method 500 may include converting (504) captured heat to electricity. Thermal to electric converters may be coupled to the inner component core for converting heat to electrical energy. The method 500 may include cooling (506) fluids using the harvested electricity. The method 500 may include cooling (508) the mold an injection molding machine.

FIG. 6 is an illustration of an example augmentation device 600. An augmentation device 600 may be used to heat the component of a manufacturing machine, such as a barrel of an injection molding machine, while also generating a cold exterior surface temperature which is captured and used to cool the machine. For example, the molding tool may be cooled while the barrel is heated. In some implementations, electrical energy is applied to the TECs 606. In some implementations, the TECs 606 produce a hot surface and a cold surface when electrical energy is applied. The heat may be used to warm a portion of the machine, such as the barrel of an injection molding machine, and the cold source is used for the machine's cooling system.

The structure of the augmentation device may be similar to the harvesting device as described above. The augmentation device may include an outer component 602. The outer component 602 may act as an insulator. The outer component 602 may also protect the components housed within the outer component 602. In some implementations, the augmentation device is a separate from the harvesting device. In some implementations, the augmentation device and the harvesting device are incorporated into a single unit. An operator may, for example, operate the device in harvesting mode or augmentation mode.

In some implementations, the augmentation device is designed with two halves. The two halves may, for example, wrap around the barrel of an injection molding machine. The augmentation device may also be designed with a one piece outer component 602. The augmentation device may also include a heat exchanger 604. The heat exchanger 604 may be removable. In some implementations, the heat exchanger 604 is located between the conductive inner component 606 and the outer component 602. The augmentation device may also include an inner component 606 with TECs.

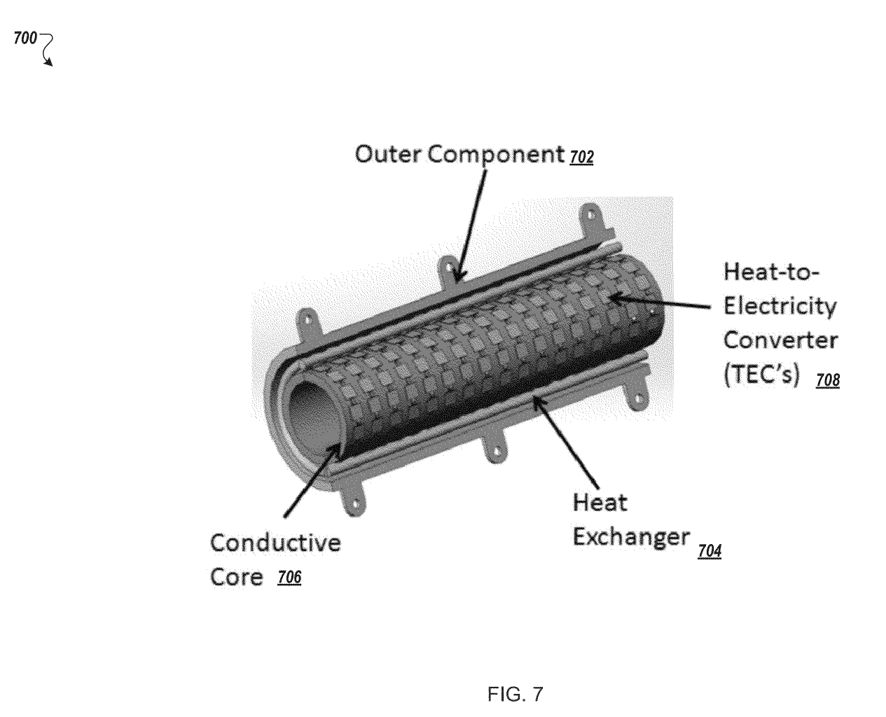

FIG. 7 is a cross sectional view of an example augmentation device 700. The augmentation device 700 may include an inner component 706 that is made of a conductive material to form a conductive core. TECs may be mounted on the inner component 706. The inner component 706 may transfer heat to the machine, such as the barrel of an injection molding machine, from the TECs 708. In some implementations, electricity is inputted to the augmentation device 700. The electricity may be applied to the TECs 708. The TECs 708 may have two sides. In some implementations, the TECs 708 produces a hot side and a cold side when the electricity is supplied augmentation device. The hot side may contact the conductive inner core and heat, for example, the barrel of an injection molding machine. This may reduce the amount of time required to heat the barrel during the startup of a manufacturing machine, such as an injection molding machine.

The cold side of the TECs 708 may contact the heat exchanger 704. The heat exchanger 704 may be used to cool fluids that are used to cool the manufacturing machine. The cold fluids may be supplied to the cooling system for the machine. The cooling system may be used to cool down the machine. For example, the cooling system may be used to cool the molding tool to assist in solidifying the molded piece before it is ejected from the tool.

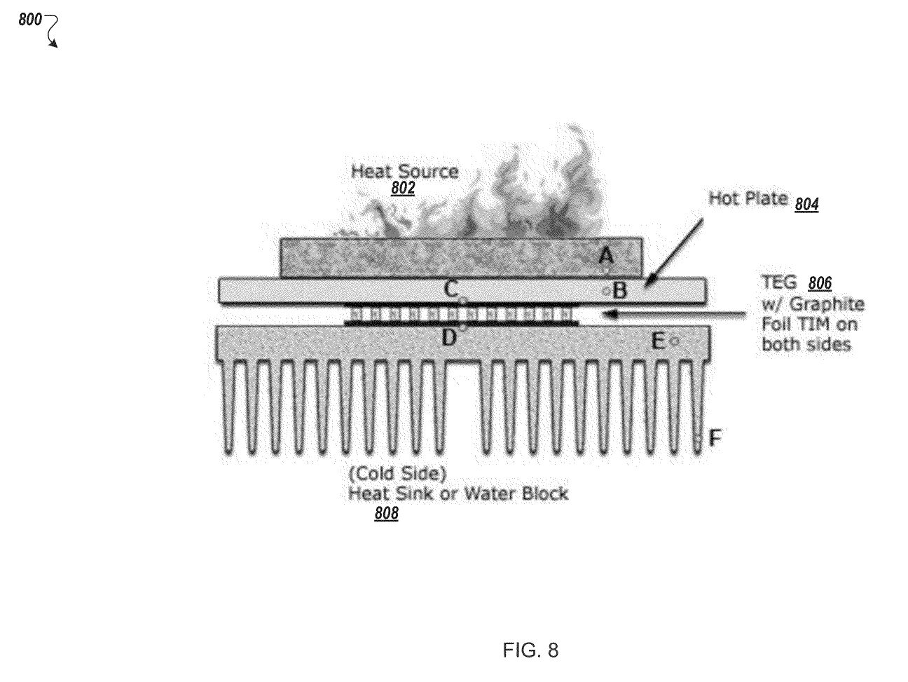

FIG. 8 is a cross sectional view of an example thermal-to-electric converted mounted between a hot plate and a heat sink. As discussed above, the hot plate 804 may be heated by a heat source 802. The heat source 802 may be, for example, a barrel of an injection molding machine. The harvesting device, as discussed with reference to FIG. 2, may include a heat sink on the cold side of the TECs 808. The heat sink may increase energy recovery by creating a larger difference between the hot side 804 and cold side 808 of the TECs 806.

In some implementations, the disclosed technology may be used on several machines in a manufacturing plant. Multiple manufacturing machines may be equipped with the harvesting device and/or augmentation device. Each machine may operate independently such that the electricity generated by a harvesting device installed on a machine may be used in association with that machine. In some implementations, the machines may be networked together to share common resources such as a cooling system and/or a central energy management system. The energy management system may be used to manage energy captured by a harvesting system. The energy management system may be used to manage energy used by an augmentation system. The energy management system may be used to control the cooling system. This may include controlling where power for operating the cooling system is sourced from.

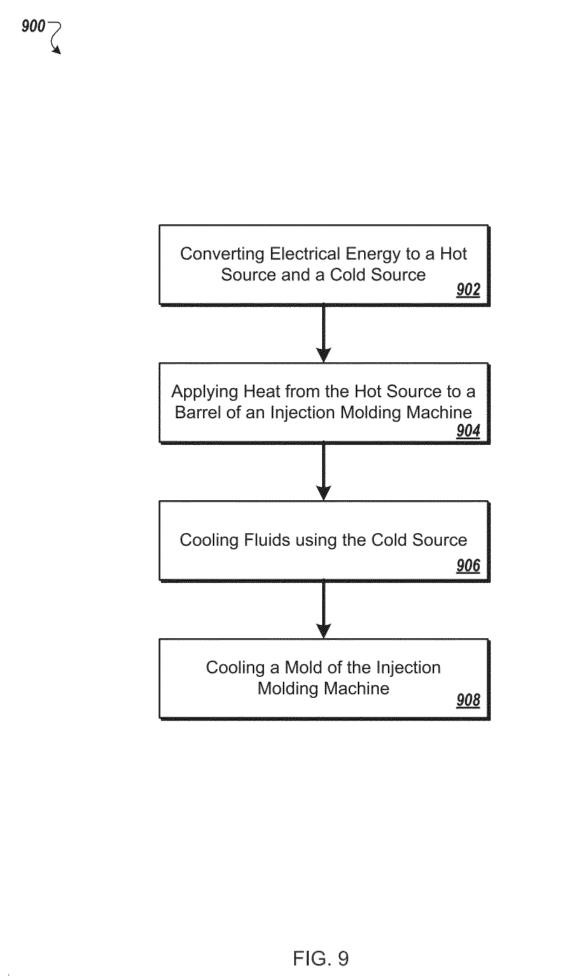

FIG. 9 is an example method 900 of using an augmentation device. Method 900 may be used for converting electrical energy to (i) heat that is applied to a barrel of a molding machine to melt material inside the barrel and (ii) a cold source that is used to cool a portion of the molding machine.

The method 900 may include converting (902) electrical energy to a hot source and a cold source. Thermal to electric converters may be used for converting electrical energy to a heat source and a cold source. The method 900 may include applying (904) heat from the hot source to a barrel of an injection molding machine. An inner component core, coupled to the thermal to electric converters, may be used to apply heat to the barrel of the molding machine. The inner component may be made from copper, aluminum, or iron.

The method 900 may include cooling (906) fluids using the cold source. A heat exchanger may be located between the inner component core and an outer component. The heat exchanger may be coupled to the cold source and used to cool fluids that are used to cool the molding machine. The method 900 may include cooling (908) a mold of the injection molding machine using the fluids that are cooled by the heat exchanger.

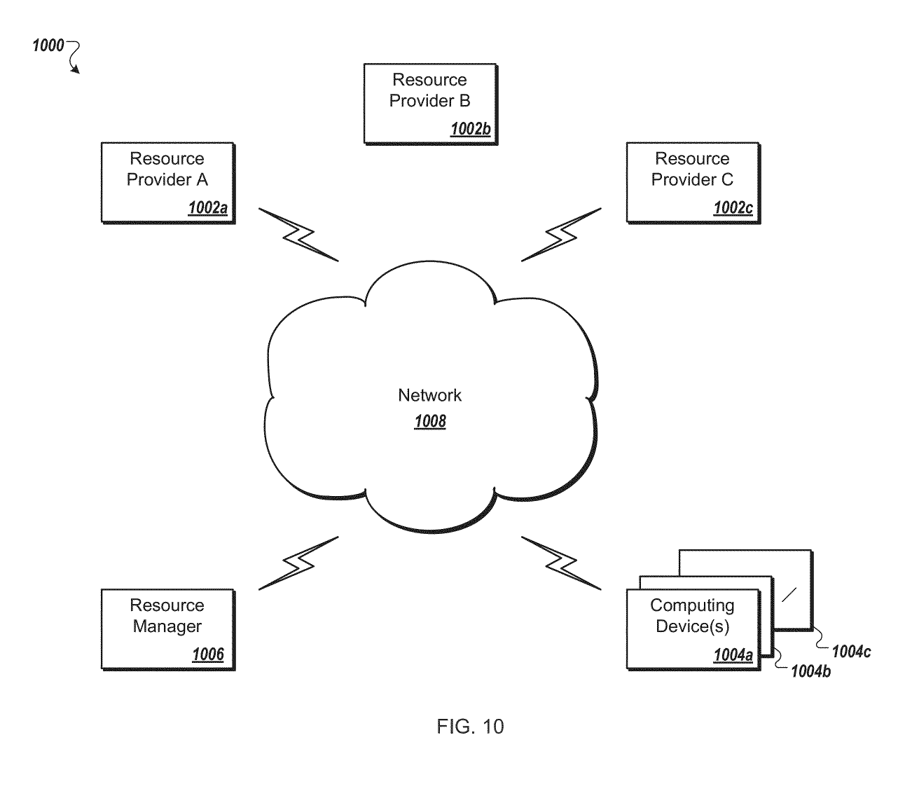

As shown in FIG. 10, an implementation of a network environment 1000 for capturing waste heat from manufacturing equipment and converting the heat to electricity and/or providing heating and cooling to manufacturing equipment is shown and described. In brief overview, referring now to FIG. 10, a block diagram of an exemplary cloud computing environment 1000 is shown and described. The cloud computing environment 1000 may include one or more resource providers 1002a, 1002b, 1002c (collectively, 1002). Each resource provider 1002 may include computing resources. In some implementations, computing resources may include any hardware and/or software used to process data. For example, computing resources may include hardware and/or software capable of executing algorithms, computer programs, and/or computer applications. In some implementations, exemplary computing resources may include application servers and/or databases with storage and retrieval capabilities. Each resource provider 1002 may be connected to any other resource provider 1002 in the cloud computing environment 1000. In some implementations, the resource providers 1002 may be connected over a computer network 1008. Each resource provider 1002 may be connected to one or more computing device 1004a, 1004b, 1004c (collectively, 1004), over the computer network 1008.

The cloud computing environment 1000 may include a resource manager 1006. The resource manager 1006 may be connected to the resource providers 1002 and the computing devices 1004 over the computer network 1008. In some implementations, the resource manager 1006 may facilitate the provision of computing resources by one or more resource providers 1002 to one or more computing devices 1004. The resource manager 1006 may receive a request for a computing resource from a particular computing device 1004. The resource manager 1006 may identify one or more resource providers 1002 capable of providing the computing resource requested by the computing device 1004. The resource manager 1006 may select a resource provider 1002 to provide the computing resource. The resource manager 1006 may facilitate a connection between the resource provider 1002 and a particular computing device 1004. In some implementations, the resource manager 1006 may establish a connection between a particular resource provider 1002 and a particular computing device 1004. In some implementations, the resource manager 1006 may redirect a particular computing device 1004 to a particular resource provider 1002 with the requested computing resource.

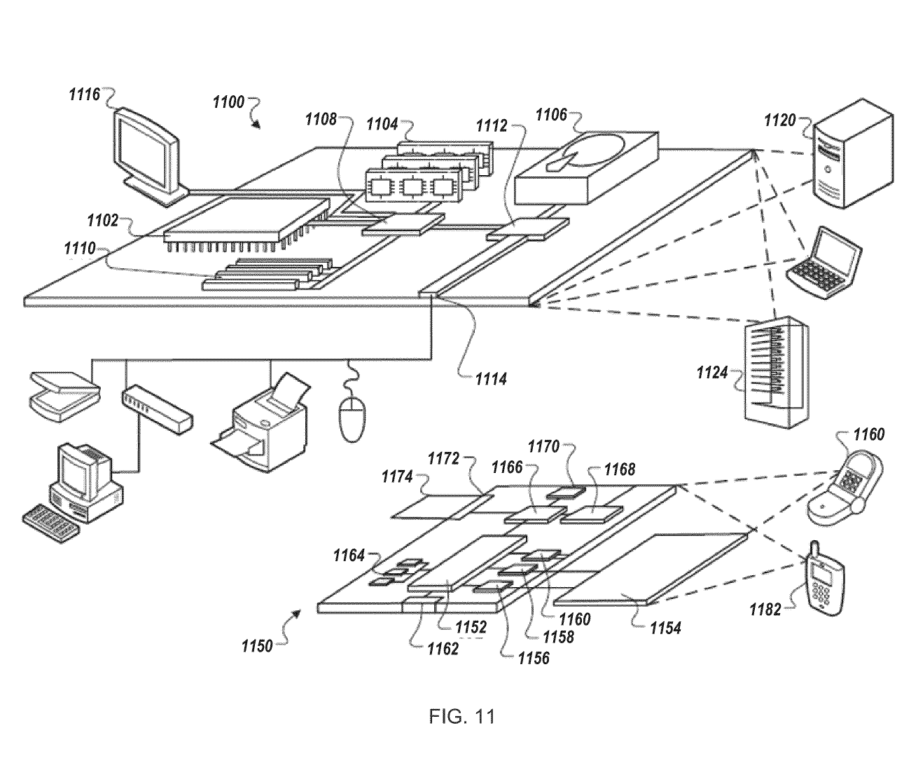

FIG. 11 shows an example of a computing device 1100 and a mobile computing device 1150 that can be used to implement the techniques described in this disclosure. The computing device 1100 is intended to represent various forms of digital computers, such as laptops, desktops, workstations, personal digital assistants, servers, blade servers, mainframes, and other appropriate computers. The mobile computing device 1150 is intended to represent various forms of mobile devices, such as personal digital assistants, cellular telephones, smart-phones, and other similar computing devices. The components shown here, their connections and relationships, and their functions, are meant to be examples only, and are not meant to be limiting.

The computing device 1100 includes a processor 1102, a memory 1104, a storage device 1106, a high-speed interface 1108 connecting to the memory 1104 and multiple high-speed expansion ports 1110, and a low-speed interface 1112 connecting to a low-speed expansion port 1114 and the storage device 1106. Each of the processor 1102, the memory 1104, the storage device 1106, the high-speed interface 1108, the high-speed expansion ports 1110, and the low-speed interface 1112, are interconnected using various busses, and may be mounted on a common motherboard or in other manners as appropriate. The processor 1102 can process instructions for execution within the computing device 1100, including instructions stored in the memory 1104 or on the storage device 1106 to display graphical information for a GUI on an external input/output device, such as a display 1116 coupled to the high-speed interface 1108. In other implementations, multiple processors and/or multiple buses may be used, as appropriate, along with multiple memories and types of memory. Also, multiple computing devices may be connected, with each device providing portions of the necessary operations (e.g., as a server bank, a group of blade servers, or a multi-processor system).

The memory 1104 stores information within the computing device 1100. In some implementations, the memory 1104 is a volatile memory unit or units. In some implementations, the memory 1104 is a non-volatile memory unit or units. The memory 1104 may also be another form of computer-readable medium, such as a magnetic or optical disk.

The storage device 1106 is capable of providing mass storage for the computing device 1100. In some implementations, the storage device 1106 may be or contain a computer-readable medium, such as a floppy disk device, a hard disk device, an optical disk device, or a tape device, a flash memory or other similar solid state memory device, or an array of devices, including devices in a storage area network or other configurations. Instructions can be stored in an information carrier. The instructions, when executed by one or more processing devices (for example, processor 1102), perform one or more methods, such as those described above. The instructions can also be stored by one or more storage devices such as computer- or machine-readable mediums (for example, the memory 1104, the storage device 1106, or memory on the processor 1102).

The high-speed interface 1108 manages bandwidth-intensive operations for the computing device 1100, while the low-speed interface 1112 manages lower bandwidth-intensive operations. Such allocation of functions is an example only. In some implementations, the high-speed interface 1108 is coupled to the memory 1104, the display 1116 (e.g., through a graphics processor or accelerator), and to the high-speed expansion ports 1110, which may accept various expansion cards (not shown). In the implementation, the low-speed interface 1112 is coupled to the storage device 1106 and the low-speed expansion port 1114. The low-speed expansion port 1114, which may include various communication ports (e.g., USB, Bluetooth®, Ethernet, wireless Ethernet) may be coupled to one or more input/output devices, such as a keyboard, a pointing device, a scanner, or a networking device such as a switch or router, e.g., through a network adapter.

The computing device 1100 may be implemented in a number of different forms, as shown in the figure. For example, it may be implemented as a standard server 1120, or multiple times in a group of such servers. In addition, it may be implemented in a personal computer such as a laptop computer 1122. It may also be implemented as part of a rack server system 1124. Alternatively, components from the computing device 1100 may be combined with other components in a mobile device (not shown), such as a mobile computing device 1150. Each of such devices may contain one or more of the computing device 1100 and the mobile computing device 1150, and an entire system may be made up of multiple computing devices communicating with each other.

The mobile computing device 1150 includes a processor 1152, a memory 1164, an input/output device such as a display 1154, a communication interface 1166, and a transceiver 1168, among other components. The mobile computing device 1150 may also be provided with a storage device, such as a micro-drive or other device, to provide additional storage. Each of the processor 1152, the memory 1164, the display 1154, the communication interface 1166, and the transceiver 1168, are interconnected using various buses, and several of the components may be mounted on a common motherboard or in other manners as appropriate.

The processor 1152 can execute instructions within the mobile computing device 1150, including instructions stored in the memory 1164. The processor 1152 may be implemented as a chipset of chips that include separate and multiple analog and digital processors. The processor 1152 may provide, for example, for coordination of the other components of the mobile computing device 1150, such as control of user interfaces, applications run by the mobile computing device 1150, and wireless communication by the mobile computing device 1150.

The processor 1152 may communicate with a user through a control interface 1158 and a display interface 1156 coupled to the display 1154. The display 1154 may be, for example, a TFT (Thin-Film-Transistor Liquid Crystal Display) display or an OLED (Organic Light Emitting Diode) display, or other appropriate display technology. The display interface 1156 may comprise appropriate circuitry for driving the display 1154 to present graphical and other information to a user. The control interface 1158 may receive commands from a user and convert them for submission to the processor 1152. In addition, an external interface 1162 may provide communication with the processor 1152, so as to enable near area communication of the mobile computing device 1150 with other devices. The external interface 1162 may provide, for example, for wired communication in some implementations, or for wireless communication in other implementations, and multiple interfaces may also be used.

The memory 1164 stores information within the mobile computing device 1150. The memory 1164 can be implemented as one or more of a computer-readable medium or media, a volatile memory unit or units, or a non-volatile memory unit or units. An expansion memory 1174 may also be provided and connected to the mobile computing device 1150 through an expansion interface 1172, which may include, for example, a SIMM (Single In Line Memory Module) card interface. The expansion memory 1174 may provide extra storage space for the mobile computing device 1150, or may also store applications or other information for the mobile computing device 1150. Specifically, the expansion memory 1174 may include instructions to carry out or supplement the processes described above, and may include secure information also. Thus, for example, the expansion memory 1174 may be provided as a security module for the mobile computing device 1150, and may be programmed with instructions that permit secure use of the mobile computing device 1150. In addition, secure applications may be provided via the SIMM cards, along with additional information, such as placing identifying information on the SIMM card in a non-hackable manner.

The memory may include, for example, flash memory and/or NVRAM memory (non-volatile random access memory), as discussed below. In some implementations, instructions are stored in an information carrier and, when executed by one or more processing devices (for example, processor 1152), perform one or more methods, such as those described above. The instructions can also be stored by one or more storage devices, such as one or more computer- or machine-readable mediums (for example, the memory 1164, the expansion memory 1174, or memory on the processor 1152). In some implementations, the instructions can be received in a propagated signal, for example, over the transceiver 1168 or the external interface 1162.

The mobile computing device 1150 may communicate wirelessly through the communication interface 1166, which may include digital signal processing circuitry where necessary. The communication interface 1166 may provide for communications under various modes or protocols, such as GSM voice calls (Global System for Mobile communications), SMS (Short Message Service), EMS (Enhanced Messaging Service), or MMS messaging (Multimedia Messaging Service), CDMA (code division multiple access), TDMA (time division multiple access), PDC (Personal Digital Cellular), WCDMA (Wideband Code Division Multiple Access), CDMA2000, or GPRS (General Packet Radio Service), among others. Such communication may occur, for example, through the transceiver 1168 using a radio-frequency. In addition, short-range communication may occur, such as using a Bluetooth®, Wi-Fi™, or other such transceiver (not shown). In addition, a GPS (Global Positioning System) receiver module 1170 may provide additional navigation- and location-related wireless data to the mobile computing device 1150, which may be used as appropriate by applications running on the mobile computing device 1150.

The mobile computing device 1150 may also communicate audibly using an audio codec 1160, which may receive spoken information from a user and convert it to usable digital information. The audio codec 1160 may likewise generate audible sound for a user, such as through a speaker, e.g., in a handset of the mobile computing device 1150. Such sound may include sound from voice telephone calls, may include recorded sound (e.g., voice messages, music files, etc.) and may also include sound generated by applications operating on the mobile computing device 1150.

The mobile computing device 1150 may be implemented in a number of different forms, as shown in the figure. For example, it may be implemented as a cellular telephone 1180. It may also be implemented as part of a smart-phone 1182, personal digital assistant, or other similar mobile device.

Various implementations of the systems and techniques described here can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

These computer programs (also known as programs, software, software applications or code) include machine instructions for a programmable processor, and can be implemented in a high-level procedural and/or object-oriented programming language, and/or in assembly/machine language. As used herein, the terms machine-readable medium and computer-readable medium refer to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term machine-readable signal refers to any signal used to provide machine instructions and/or data to a programmable processor.

To provide for interaction with a user, the systems and techniques described here can be implemented on a computer having a display device (e.g., a CRT (cathode ray tube) or LCD (liquid crystal display) monitor) for displaying information to the user and a keyboard and a pointing device (e.g., a mouse or a trackball) by which the user can provide input to the computer. Other kinds of devices can be used to provide for interaction with a user as well; for example, feedback provided to the user can be any form of sensory feedback (e.g., visual feedback, auditory feedback, or tactile feedback); and input from the user can be received in any form, including acoustic, speech, or tactile input.

The systems and techniques described here can be implemented in a computing system that includes a back end component (e.g., as a data server), or that includes a middleware component (e.g., an application server), or that includes a front end component (e.g., a client computer having a graphical user interface or a Web browser through which a user can interact with an implementation of the systems and techniques described here), or any combination of such back end, middleware, or front end components. The components of the system can be interconnected by any form or medium of digital data communication (e.g., a communication network). Examples of communication networks include a local area network (LAN), a wide area network (WAN), and the Internet.

The computing system can include clients and servers. A client and server are generally remote from each other and typically interact through a communication network. The relationship of client and server arises by virtue of computer programs running on the respective computers and having a client-server relationship to each other.

In view of the structure, functions and apparatus of the systems and methods described here, in some implementations, an apparatus and method for capturing waste heat from manufacturing equipment and converting the heat to electricity and/or providing heating and cooling to manufacturing equipment are provided. Having described certain implementations of methods and apparatus for supporting capturing waste heat from manufacturing equipment and converting the heat to electricity and/or providing heating and cooling to manufacturing equipment, it will now become apparent to one of skill in the art that other implementations incorporating the concepts of the disclosure may be used. Therefore, the disclosure should not be limited to certain implementations, but rather should be limited only by the spirit and scope of the following claims.

Throughout the description, where apparatus and systems are described as having, including, or comprising specific components, or where processes and methods are described as having, including, or comprising specific steps, it is contemplated that, additionally, there are apparatus, and systems of the disclosed technology that consist essentially of, or consist of, the recited components, and that there are processes and methods according to the disclosed technology that consist essentially of, or consist of, the recited processing steps.

It should be understood that the order of steps or order for performing certain action is immaterial so long as the disclosed technology remains operable. Moreover, two or more steps or actions may be conducted simultaneously.

1. A harvesting apparatus for converting waste energy from a barrel of a molding machine from heat to electricity, the system comprising:
an inner component core for capturing heat from a barrel of a molding machine;
one or more thermal-to-electric converters coupled to the inner component core for converting heat to electrical energy; and
an outer component surrounding at least a portion of the inner component core and the one or more thermal-to-electric converters, wherein the outer component is an insulator and assists in heat conduction from the barrel of the molding machine to the one or more thermal-to-electric converters and in containing thermal waste energy.

2. The harvesting apparatus of claim 1, comprising two or more thermal-to-electric converters positioned along the barrel according to a desired temperature distribution along the length of the barrel.

3. The harvesting apparatus of claim 1, wherein the inner component core is in physical contact with the barrel of the molding machine.

4. The harvesting apparatus of claim 1, wherein the one or more thermal-to-electric converters are mounted on the inner component core.

5. The harvesting apparatus of claim 1, wherein the one or more thermal-to-electric converters are removable.

6. The harvesting apparatus of claim 1, wherein the one or more thermal-to-electric are coupled to an energy management system and the energy management system is programmable to accommodate the material in a molding process.

7. The harvesting apparatus of claim 1, comprising a plurality of thermal-to-electric converters arranged in a grid.

8. The harvesting apparatus of claim 1, wherein the one or more thermal-to-electric converters is a single thermal-to-electric converter with a curved shape configured to wrap around the inner component core.

9. The harvesting apparatus of claim 1, wherein each of the inner component core and the outer component has a two-piece design such that the harvesting apparatus is removable.

10. A augmentation apparatus for use with a molding machine, comprising:
one or more thermal-to-electric converters for converting electrical energy to a heat source and a cold source;
an inner component core, coupled to the one or more thermal-to-electric converters, for applying heat to a barrel of a molding machine;
an outer component surrounding at least a portion of the inner component core and the one or more thermal-to-electric converters, wherein the outer component is an insulator and assists in heat conduction from the one or more thermal-to-electric converters to the barrel of the molding machine and in containing thermal waste energy; and
a heat exchanger located between the inner component core and the outer component, wherein the heat exchanger is coupled to the cold source and used to cool a heat transfer fluid.

11. The augmentation apparatus of claim 10, comprising two or more thermal-to-electric converters positioned along the barrel according to a desired temperature distribution along the length of the barrel.

12. The augmentation apparatus of claim 10, wherein the inner component core is in physical contact with the barrel of the molding machine.

13. The augmentation apparatus of claim 10, wherein the thermal-to-electric converters are mounted on the inner component core.

14. The augmentation apparatus of claim 10, wherein the one or more thermal-to-electric converters are removable.

15. The augmentation apparatus of claim 10, wherein the one or more thermal-to-electric are coupled to an energy management system and the energy management system is programmable to accommodate the material in a molding process.

16. The augmentation apparatus of claim 10, comprising a plurality of thermal-to-electric converters arranged in a grid.

17. The augmentation apparatus of claim 10, wherein the one or more thermal-to-electric converters is a single thermal-to-electric converter with a curved shape configured to wrap around the inner component core.

18. The augmentation apparatus of claim 10, wherein each of the inner component core and outer component has a two-piece design such that the augmentation apparatus is removable.

19. The augmentation apparatus of claim 10, wherein the heat exchange fluid is a refrigerant.

20. A method of using a harvesting system for converting waste heat from a barrel of a molding machine to electricity comprising:
capturing, via an inner component core of a harvesting system, heat from a barrel of a molding machine, wherein the inner component is made from at least one material selected from the group consisting of copper, aluminum, and iron; and
converting, via one or more thermal-to-electric converters coupled to the inner component core, the captured heat to electrical energy;
wherein:
the harvesting system includes an outer component surrounding at least a portion of the inner component core and the one or more thermal-to-electric converters, wherein the outer component is an insulator and assists in heat conduction from the barrel of the molding machine to the one or more thermal-to-electric converters and in containing thermal waste energy;
the harvesting system is used to harvest waste heat from a molding machine; and
the electricity produced by the harvesting system is used to augment a cooling system used to cool the mold of the molding machine.

21-23. (canceled)
